(19) United States
(12) Patent Application Publication
(10) Pub. No.: US 2014/0026960 A1
(43) Pub. Date: Jan. 30, 2014

(54) ENCAPSULENT FOR A PHOTOVOLTAIC MODULE

(71) Applicants: Stéphane Bizet, Barc (FR); Samuel Devisme, Rouen (FR); Thomas Fine, Lyon (FR); Dominique Jousset, Bougival (FR)

(72) Inventors: Stéphane Bizet, Barc (FR); Samuel Devisme, Rouen (FR); Thomas Fine, Lyon (FR); Dominique Jousset, Bougival (FR)

(73) Assignee: ARKEMA FRANCE, Colombes (FR)

(21) Appl. No.: 13/984,468

(22) PCT Filed: Jan. 12, 2012
(86) PCT No.: PCT/FR2012/050083

§ 371 Date: Oct. 15, 2013

(30) Foreign Application Priority Data
Feb. 11, 2011 (FR) 1151110

(51) Int. Cl. H01L 31/048

(52) U.S. Cl. CPC H01L 31/0481
USPC 136/259; 428/520

(57) ABSTRACT

An encapsulant for a photovoltaic module, intended to coat a photovoltaic cell, including at least two adjacent thermoplastic layers together forming a core-skin assembly: the skin layer is a polyamide graft polymer including a polyolefin backbone representing 50 wt % to 95 wt % of the polyamide graft polymer, containing a residue of at least one unsaturated monomer (X) and at least one polyamide graft, representing 5 wt % to 50 wt % of said polyamide graft polymer; the polyolefin backbone and the polyamide graft of the skin layer are chosen so that the polyamide graft polymer has a flow temperature greater than or equal to 75° C. and less than or equal to 160° C., this flow temperature being defined as the highest temperature out of the melting temperature and the glass transition temperature of the polyamide graft and of the polyolefin backbone.

### FIELD OF THE INVENTION

One subject of the invention is an encapsulant for a photovoltaic module having a particular core-skin structure that gives it optimum properties for this application. The present invention also relates to a photovoltaic module, or to its use in such a module, comprising, besides the encapsulant layer, at least one adjacent layer forming a “frontsheet” or “backsheet”, more generally these three successive layers, “frontsheet”, encapsulant and “backsheet”.

Global warming, linked to the greenhouse gases released by fossil fuels, has led to the development of alternative energy solutions which do not emit such gases during their operation, such as for example photovoltaic modules. A photovoltaic module comprises a “photovoltaic cell”, this cell being capable of converting light energy into electricity.

There are many types of photovoltaic panel structures.

In FIG. 1, a conventional photovoltaic cell has been represented; this photovoltaic cell 10 comprises cells 12, one cell containing a photovoltaic sensor 14, generally based on silicon that is treated in order to obtain photoelectric properties, in contact with electron collectors 16 placed above (upper collectors) and below (lower collectors) the photovoltaic sensor. The upper collectors 16 of one cell are connected to the lower collectors 16 of another cell 12 by conducting bars 18, generally consisting of an alloy of metals. All these cells 12 are connected to one another, in series and/or in parallel, in order to form the photovoltaic cell 10. When the photovoltaic cell 10 is placed under a light source, it delivers a continuous electric current, which may be recovered at the terminals 19 of the cell 10.

With reference to FIG. 2, the photovoltaic module 20 comprises the photovoltaic cell 10 from FIG. 1 encased in an “encapsulant”, the latter being composed of an upper portion 22 and a lower portion 23. An upper protective layer 24 (known under the term “frontsheet”, used hereinafter) and a protective layer on the back of the module (known under the term “backsheet”, also used hereinafter) 26 are positioned on either side of the encapsulated cell.

The impact and moisture protection of the photovoltaic cell 10 is provided by the upper protective layer 24, generally made of glass.

The backsheet 26, for example a multilayer film based on a fluoropolymer and polyethylene terephthalate, contributes to the moisture protection of the photovoltaic module 20 and to the electrical insulation of the cells 12 to prevent any contact with the outside environment.

The encapsulant 22 must perfectly adopt the shape of the space existing between the photovoltaic cell 10 and the protective layers 24 and 26 in order to avoid the presence of air, which would limit the efficiency of the photovoltaic module. The encapsulant 22 must also prevent contact of the cells 12 with water and oxygen from the air, in order to limit the corrosion thereof. The upper portion of the encapsulant 22 is between the cell 10 and the upper protective layer 24. The lower portion of the encapsulant 22 is between the cell 10 and the backsheet 26.

In the presence of solar radiation, a temperature rise is created inside the solar module and temperatures of 80° C. (or more) may be achieved, which requires that the layers be perfectly bonded to one another throughout the life cycle of the module.

### PRIOR ART

Generally, due to an insufficient impermeability of the encapsulant to water vapor, it is necessary to join two layers thereto, positioned on either side of this encapsulant layer and forming the “frontsheet” and the “backsheet” (then forming a photovoltaic module in the form of a three-layer structure with the encapsulant layer as the central layer, sandwiched between the two other layers), the latter two layers having particularly advantageous properties, in particular regarding the water impermeability properties.

Currently, known from document WO 09/138,679 is a thermoplastic composition constituting the encapsulant that has particularly advantageous properties linked to the nanostructurations thereof, namely a good transparency, a good creep resistance, very satisfactory mechanical properties and an ease of processing. However, the thermoplastic compositions for which the polyolefin backbone possesses a high melting point may have insufficient adhesion to various substrates, in particular in a wet medium or during thermal cycling. The substrates in question may be other thermoplastic coatings or glass.

In order to overcome this drawback, the encapsulant layer is combined with “frontsheet” and “backsheet” layers by chemical techniques (addition of a binder that ensures the joining of two layers) or physicochemical techniques (surface treatment, for example of corona type), but these two methods are not satisfactory since they consist, apart from a not inconsiderable additional cost (material, specific tools, implementation time), of an operation that is sometimes complex for a result that is often disappointing.

### BRIEF DESCRIPTION OF THE INVENTION

It has been observed by the applicant, after various experiments and manipulations, that a particular structure of the encapsulant could alone make it possible to solve the problems of this encapsulant for photovoltaic modules of the prior art while retaining all of their excellent properties.

It has indeed been demonstrated, after multiple experiments, that a relatively minor variation of the polyamide graft polymer known by the applicant (WO 09/138,679) was capable not only of retaining its mechanical properties but also of exhibiting, in particular, adhesion properties essential for its attachment to the “backsheet” and “frontsheet” layers, it being noted that the polyamide graft polymer of the aforementioned document is incapable of being correctly attached (very poor results in the peel tests) to the standard materials forming the “backsheet” and “frontsheet”, and especially those materials presented in the present application.

Thus, the present invention relates to a photovoltaic module encapsulant, intended to encase a photovoltaic cell, comprising two adjacent thermoplastic layers forming a core-skin assembly, characterized in that:
the core layer consists of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
   the polyamide graft is attached to the polyolefin backbone by the residue of the unsaturated monomer (X) comprising a function capable of reacting via a condensation reaction with a polyamide having at least one amine end group and/or at least one carboxylic acid end group,
   the residue of the unsaturated monomer (X) is attached to the backbone by grafting or copolymerization,
the skin layer consists of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
   the polyamide graft is attached to the polyolefin backbone by the residue of the unsaturated monomer (X) comprising a function capable of reacting via a condensation reaction with a polyamide having at least one amine end group and/or at least one carboxylic acid end group,
   the residue of the unsaturated monomer (X) is attached to the backbone by grafting or copolymerization,
   the polyolefin backbone and the polyamide graft being chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone.

Other characteristics of the invention are presented below:
the skin layer and the core layer are nanostructured;
for the core layer as for the skin layer, the number-average molar mass of polyamide graft is within the range extending from 1000 to 5000 g/mol, preferably within the range extending from 2000 to 3000 g·mol⁻¹;
for the core layer as for the skin layer, the number of monomers (X) attached to the polyolefin backbone is greater than or equal to 1.3 and/or less than or equal to 10;
the polyolefin backbone and the polyamide graft of the core layer are chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone;
for the core layer as for the skin layer, the at least one polyamide graft comprises at least one copolyamide;
for the core layer, the polyolefin backbone has a melting temperature of greater than or equal to 95° C.;
for the skin layer, the polyolefin backbone does not have a melting temperature or has a melting temperature below 95° C.;
the polyolefin backbone and the polyamide graft of the core layer are chosen so that said polyamide graft polymer has a flow temperature of greater than 160° C., this flow temperature being defined as the highest temperature among the melting temperatures and glass transition temperatures of the polyamide graft and of the polyolefin backbone;
the encapsulant according to the invention consists of two adjacent layers that form a core-skin assembly or of three adjacent layers that form a skin-core-skin assembly where the two skin layers surround the core layer and are preferably identical.

The invention also relates to the use of the encapsulant as described above in a photovoltaic module.

Finally, the invention relates to a photovoltaic module comprising a structure consisting of a combination of at least one encapsulant and a frontsheet or backsheet, characterized in that the encapsulant is as described above.

### DESCRIPTION OF THE APPENDED FIGURES

The description which follows is given solely by way of illustration and nonlimitingly with reference to the appended figures, in which:

FIG. 1, already described, represents an example of a photovoltaic cell, the parts (a) and (b) being ¾ views, part (a) showing a cell before connection and part (b) a view after connection of two cells; part (c) is a top view of a complete photovoltaic cell.

FIG. 2, already described, represents a cross section of a photovoltaic module, the “conventional” photovoltaic sensor of which is encapsulated by an upper encapsulant film and a lower encapsulant film.

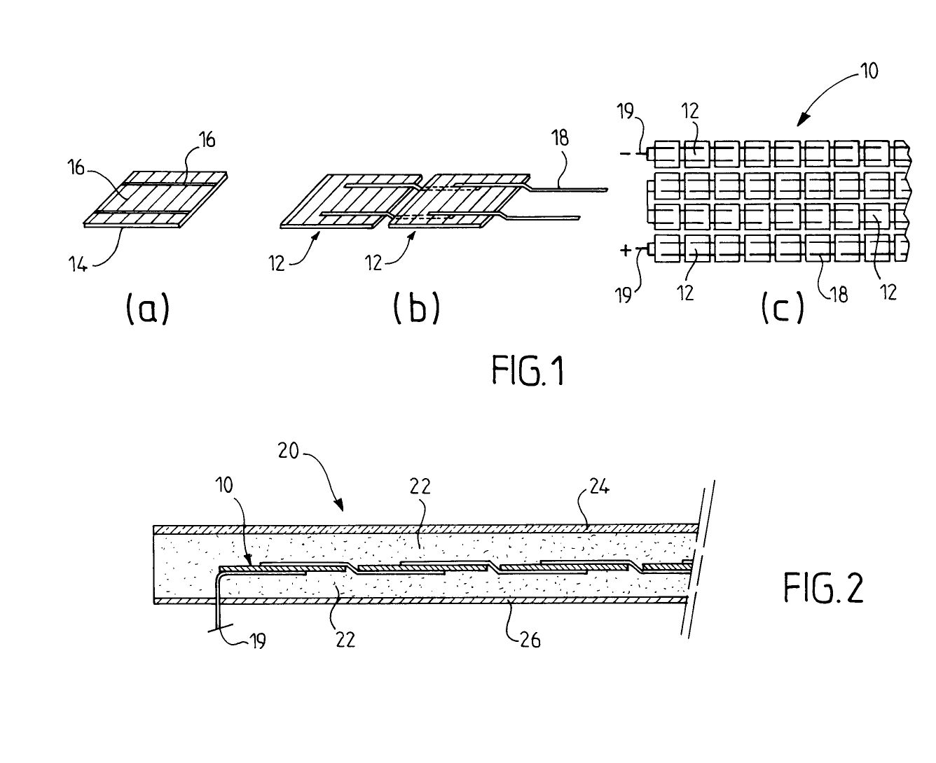

### DETAILED DESCRIPTION OF THE INVENTION

### I. Core Layer of the Encapsulant

Regarding firstly the core layer of the encapsulant, it consists here of a layer which can be in two distinct forms resulting nevertheless from one and the same family of compounds. The characteristics common to these types of molecules, belonging to the same family of compounds, are expressed as follows:

Specifically, they are, in both cases, a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
the polyamide graft is attached to the polyolefin backbone by the residue of the unsaturated monomer (X) comprising a function capable of reacting via a condensation reaction with a polyamide having at least one amine end group and/or at least one carboxylic acid end group,
the residue of the unsaturated monomer (X) is attached to the backbone by grafting or copolymerization.

Besides these characteristics common to the possible types of molecules forming the core of the encapsulant, the core layer could comprise a certain number of components intended to confer particular additional properties and/or to improve the intrinsic properties of the material forming the main part of the core layer of the encapsulant.

Plasticizers could be added in order to facilitate processing and improve the productivity of the process for manufacturing the composition and the structures. Mention will be made, as examples, of paraffinic, aromatic or naphthalenic mineral oils which also make it possible to improve the adhesive strength of the composition according to the invention. Mention may also be made, as plasticizers, of phthalates, azelates, adipates, and tricresyl phosphate.

Adhesion promoters, although not necessary, may advantageously be added in order to improve the adhesive strength of the composition when this adhesive strength must be particularly high. The adhesion promoter is a non-polymeric ingredient; it may be organic, crystalline, mineral and more preferably semi-mineral semi-organic. Among the latter, mention may be made of organic titanates or silanes, such as for example monoalkyl titanates, trichlorosilanes and trialkoxysilanes. Advantageously, use will be made of trialkoxysilanes containing an epoxy, vinyl and amine group.

In this particular application of the composition to photovoltaic modules, since the UV radiation is capable of resulting in a slight yellowing of the composition used as an encapsulant for said modules, UV stabilizers and UV absorbers, such as benzotriazole, benzophenone and other hindered amines, may be added in order to ensure the transparency of the encapsulant during its service life. These compounds may be, for example, based on benzophenone or benzotriazole. They can be added in amounts of less than 10%, and preferably of from 0.1% to 5%, by weight of the total weight of the composition.

Antioxidants could also be added in order to limit yellowing during the manufacture of the encapsulant, such as phosphorus-containing compounds (phosphonites and/or phosphites) and hindered phenolics. These antioxidants can be added in amounts of less than 10%, and preferably of from 0.1% to 5%, by weight of the total weight of the composition.

Flame retardants may also be added. These flame retardants may be halogenated or non-halogenated. Among the halogenated flame retardants, mention may be made of brominated products. Use may also be made, as non-halogenated flame retardants, of additives based on phosphorus such as ammonium phosphate, polyphosphate, phosphinate or pyrophosphate, melamine cyanurate, pentaerythritol, zeolites and also mixtures of these flame retardants. The composition may comprise these flame retardants in proportions ranging from 3% to 40% relative to the total weight of the composition.

It is also possible to add pigments, such as for example titanium dioxide and coloring or whitening compounds, in proportions generally ranging from 5% to 15% relative to the total weight of the composition.

Fillers, in particular mineral fillers, may also be added in order to improve the thermomechanical resistance of the composition. Given nonlimitingly as examples are silica, alumina or calcium carbonates or carbon nanotubes or else glass fibers. Use could be made of modified or unmodified clays, which are mixed on the nanometer scale; this makes it possible to obtain a more transparent composition.

I.a. Characteristics Common to the Two Types of Molecules Forming the Core Layer of the Encapsulant According to the Invention:

In what follows, the characteristics which are common to the two types of molecules capable of forming the core of the encapsulant according to the invention are therefore specified, then secondly (I.b.1 and I.b.2) the characteristics specific to each of these molecules will be specified.

Thus, described below is firstly what is understood by the definition of the polyolefin then by the definition relating to the graft polymer.

Regarding the polyolefin backbone relating to the skin part, it is a polymer comprising an α-olefin as monomer. Equally, what follows is also understood in connection with the core part of the encapsulant when the comonomer of the copolymer is an α-olefin.

α-Olefins having from 2 to 30 carbon atoms are preferred.

As α-olefin, mention may be made of ethylene, propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene, 1-eicosene, 1-docosene, 1-tetracosene, 1-hexacosene, 1-octacosene and 1-triacontene.

Mention may also be made of cycloolefins having from 3 to 30 carbon atoms, preferably from 3 to 20 carbon atoms, such as cyclopentane, cycloheptene, norbornene, 5-methyl-2-norbornene, tetracyclododecene and 2-methyl-1,4,5,8-dimethano-1,2,3,4,4a,5,8,8a-octahydronaphthalene; diolefins and polyolefins, such as butadiene, isoprene, 4-methyl-1,3-pentadiene, 1,4-pentadiene, 1,5-hexadiene, 1,3-hexadiene, 1,3-octadiene, 1,4-octadiene, 1,5-octadiene, 1,6-octadiene, ethylidene norbornene, vinyl norbornene, dicyclopentadiene, 7-methyl-1,6-octadiene, 4-ethylidene-8-methyl-1,7-nonadiene and 5,9-dimethyl-1,4,8-decatriene; vinylaromatic compounds such as monoalkylstyrenes or polyalkylstyrenes (including styrene, o-methylstyrene, m-methylstyrene, p-methylstyrene, o,p-dimethylstyrene, o-ethylstyrene, m-ethylstyrene and p-ethylstyrene), and derivatives comprising functional groups such as methoxystyrene, ethoxystyrene, vinylbenzoic acid, vinylmethyl benzoate, vinylbenzyl acetate, hydroxystyrene, o-chlorostyrene, p-chlorostyrene, divinyl-benzene, 3-phenylpropene, 4-phenylpropene, α-methylstyrene, vinyl chloride, 1,2-difluoroethylene, 1,2-dichloroethylene, tetrafluoroethylene and 3,3,3-trifluoro-1-propene.

Within the context of the present invention, the term “α-olefin” also comprises styrene. Propylene, and very especially ethylene, are preferred as α-olefin.

This polyolefin may be a homopolymer when a single α-olefin is polymerized in the polymer chain. Mention may be made, as examples, of polyethylene (PE) or polypropylene (PP).

This polyolefin may also be a copolymer when at least two comonomers are copolymerized in the polymer chain, one of the two comonomers referred to as the “first comonomer” being an α-olefin and the other comonomer, referred to as the “second comonomer”, is a monomer capable of polymerizing with the first monomer.

As the second comonomer, mention may be made of:
one of the α-olefins already mentioned, the latter being different from the first α-olefin comonomer,
dienes, such as for example 1,4-hexadiene, ethylidene norbornene and butadiene,
unsaturated carboxylic acid esters such as, for example, alkyl acrylates or alkyl methacrylates grouped together under the term alkyl (meth)acrylates. The alkyl chains of these (meth)acrylates may have up to 30 carbon atoms. Mention may be made, as alkyl chains, of methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, heneicosyl, docosyl, tricosyl, tetracosyl, pentacosyl, hexacosyl, heptacosyl, octacosyl, nonacosyl. Methyl, ethyl and butyl (meth)acrylates are preferred as unsaturated carboxylic acid esters,
carboxylic acid vinyl esters. As examples of carboxylic acid vinyl esters, mention may be made of vinyl acetate, vinyl versatate, vinyl propionate, vinyl butyrate or vinyl maleate. Vinyl acetate is preferred as carboxylic acid vinyl ester.

Advantageously, the polyolefin backbone comprises at least 50 mol % of the first comonomer; its density may advantageously be between 0.91 and 0.96.

The preferred polyolefin backbones consist of an ethylene/-alkyl (meth)acrylate copolymer. By using this polyolefin backbone, excellent aging, light and temperature resistance are obtained.

It would not be outside of the scope of the invention if different “second comonomers” were copolymerized in the polyolefin backbone.

According to the present invention, the polyolefin backbone contains at least one residue of an unsaturated monomer (X) that can react with an acid and/or amine function of the polyamide graft via a condensation reaction. According to the definition of the invention, the unsaturated monomer (X) is not a “second comonomer”.

As unsaturated monomer (X) included in the polyolefin backbone, mention may be made of:
unsaturated epoxides. Among these are for example aliphatic glycidyl esters and ethers such as allyl glycidyl ether, vinyl glycidyl ether, glycidyl maleate and glycidyl itaconate, glycidyl acrylate and glycidyl methacrylate. They are also, for example, alicyclic glycidyl esters and ethers such as 2-cyclohexene-1-glycidyl ether, glycidyl cyclohexene-4,5-dicarboxylate, glycidyl cyclohexene-4-carboxylate, glycidyl 5-norbornene-2-methyl-2-carboxylate and diglycidyl endo-cis-bicyclo-[2.2.1]-5-heptene-2,3-dicarboxylate. As unsaturated epoxide, glycidyl methacrylate is preferably used;
unsaturated carboxylic acids and their salts, for example acrylic acid or methacrylic acid and the salts of these same acids;
carboxylic acid anhydrides. They may be chosen, for example, from maleic, itaconic, citraconic, allyl-succinic, cyclohex-4-ene-1,2-dicarboxylic, 4-methylenecyclohex-4-ene-1,2-dicarboxylic, bicyclo-[2.2.1]hept-5-ene-2,3-dicarboxylic and x-methylbicyclo[2.2.1]hept-5-ene-2,2-dicarboxylic anhydrides. As carboxylic acid anhydride, maleic anhydride is preferably used.

The unsaturated monomer (X) is preferably chosen from an unsaturated carboxylic acid anhydride and an unsaturated epoxide. In particular, for achieving the condensation of the polyamide graft with the polyolefin backbone, in the case where the reactive end of the polyamide graft is a carboxylic acid function, the unsaturated monomer (X) is preferably an unsaturated epoxide. In the case where the reactive end of the polyamide graft is an amine function, the unsaturated monomer (X) is advantageously an unsaturated epoxide and preferably an unsaturated carboxylic acid anhydride.

According to one advantageous version of the invention, the preferred number of unsaturated monomers (X) attached, on average, to the polyolefin backbone is greater than or equal to 1.3 and/or preferably less than or equal to 10.

Thus, when (X) is maleic anhydride and the number-average molar mass of the polyolefin is 15 000 g/mol, it was found that this corresponded to an anhydride proportion of at least 0.8%, and at most 6.5%, by weight of the whole of the polyolefin backbone. These values associated with the mass of the polyamide grafts determine the proportion of polyamide and of backbone in the polyamide graft polymer.

The polyolefin backbone containing the residue of the unsaturated monomer (X) is obtained by polymerization of the monomers (first comonomer, optional second comonomer, and optionally unsaturated monomer (X)). This polymerization can be carried out by a high-pressure radical process or a process in solution, in an autoclave or tubular reactor, these processes and reactors being well known to a person skilled in the art. When the unsaturated monomer (X) is not copolymerized in the polyolefin backbone, it is grafted to the polyolefin backbone. The grafting is also an operation that is known per se. The composition would be in accordance with the invention if several different functional monomers (X) were copolymerized with and/or grafted to the polyolefin backbone.

Depending on the types and ratio of monomers, the polyolefin backbone may be semicrystalline or amorphous. In the case of amorphous polyolefins, only the glass transition temperature is observed, whereas in the case of semicrystalline polyolefins a glass transition temperature and a melting temperature (which will inevitably be higher) are observed. A person skilled in the art will only have to select the ratios of monomer and the molecular masses of the polyolefin backbone in order to be able to easily obtain the desired values of the glass transition temperature, optionally of the melting temperature, and also of the viscosity of the polyolefin backbone.

Preferably, the polyolefin has a melt flow index (MFI) between 3 and 400 g/10 min (190° C., 2.16 kg, ASTM D 1238).

The polyamide grafts may be either homopolyamides or copolyamides.

The expression “polyamide grafts” especially targets the aliphatic homopolyamides which result from the polycondensation:
of a lactam;
or of an aliphatic α,ω-aminocarboxylic acid;
or of an aliphatic diamine and an aliphatic diacid.

As examples of a lactam, mention may be made of caprolactam, oenantholactam and lauryllactam.

As examples of an aliphatic α,ω-aminocarboxylic acid, mention may be made of aminocaproic acid, 7-aminoheptanoic acid, 11-aminoundecanoic acid and 12-aminododecanoic acid.

As examples of an aliphatic diamine, mention may be made of hexamethylenediamine, dodecamethylenediamine and trimethylhexamethylenediamine.

As examples of an aliphatic diacid, mention may be made of adipic, azelaic, suberic, sebacic and dodecanedicarboxylic acids.

Among the aliphatic homopolyamides, mention may be made, by way of example and nonlimitingly, of the following polyamides: polycaprolactam (PA-6); polyundecanamide (PA-11, sold by Arkema under the brand Rilsan®); polylauryllactam (PA-12, also sold by Arkema under the brand Rilsan®); polybutylene adipamide (PA-4,6); polyhexamethylene adipamide (PA-6,6); polyhexamethylene azelamide (PA-6,9); polyhexamethylene sebacamide (PA-6,10); polyhexamethylene dodecanamide (PA-6,12); polydecamethylene dodecanamide (PA-10,12); polydecamethylene sebacamide (PA-10,10) and polydodecamethylene dodecanamide (PA-12,12).

The expression “semicrystalline polyamides” also targets cycloaliphatic homopolyamides.

Mention may especially be made of the cycloaliphatic homopolyamides which result from the condensation of a cycloaliphatic diamine and an aliphatic diacid.

As an example of a cycloaliphatic diamine, mention may be made of 4,4′-methylenebis(cyclohexylamine), also known as para-bis(aminocyclohexyl)methane or PACM, 2,2′-dimethyl-4,4′-methylenebis(cyclohexylamine), also known as bis(3-methyl-4-aminocyclohexyl)methane or BMACM.

Thus, among the cycloaliphatic homopolyamides, mention may be made of the polyamides PACM,12 resulting from the condensation of PACM with the C12 diacid, BMACM,10 and BMACM,12 resulting from the condensation of BMACM with, respectively, C10 and C12 aliphatic diacids.

The expression “polyamide grafts” also targets the semiaromatic homopolyamides that result from the condensation:
of an aliphatic diamine and an aromatic diacid, such as terephthalic acid (T) and isophthalic acid (I). The polyamides obtained are then commonly known as “polyphthalamides” or PPAs; and
of an aromatic diamine, such as xylylenediamine, and more particularly meta-xylylenediamine (MXD) and an aliphatic diacid.

Thus, nonlimitingly, mention may be made of the polyamides 6,T, 6,I, MXD,6 or else MXD,10.

The polyamide grafts used in the composition according to the invention are preferably copolyamides. These result from the polycondensation of at least two of the groups of monomers mentioned above in order to obtain homopolyamides. The term “monomer” in the present description of the copolyamides should be taken in the sense of a “repeat unit”. This is because the case where a repeat unit of the PA is formed from the combination of a diacid with a diamine is particular. It is considered that it is the combination of a diamine and a diacid, that is to say the diamine-diacid pair (in an equimolar amount), which corresponds to the monomer. This is explained by the fact that, individually, the diacid or the diamine is only one structural unit, which is not enough on its own to be polymerized in order to give a polyamide.

Thus, the copolyamides cover especially the condensation products of:
at least two lactams;
at least two aliphatic α,ω-aminocarboxylic acids;
at least one lactam and at least one aliphatic α,ω-aminocarboxylic acid;
at least two diamines and at least two diacids;
at least one lactam with at least one diamine and at least one diacid;
at least one aliphatic α,ω-aminocarboxylic acid with at least one diamine and at least one diacid,
   the diamine(s) and the diacid(s) possibly being, independently of one another, aliphatic, cycloaliphatic or aromatic.

Depending on the types and ratio of monomers, the copolyamides may be semicrystalline or amorphous. In the case of amorphous copolyamides, only the glass transition temperature is observed, whereas in the case of semicrystalline copolyamides a glass transition temperature and a melting temperature (which will inevitably be higher) are observed.

Among the amorphous copolyamides that can be used within the context of the invention, mention may be made, for example, of the copolyamides containing semiaromatic monomers.

Among the copolyamides, it is also possible to use semicrystalline copolyamides and particularly those of the PA-6/11, PA-6/12 and PA-6/11/12 type.

The degree of polymerization may vary to a large extent; depending on its value it is a polyamide or a polyamide oligomer.

Advantageously, the polyamide grafts are monofunctional.

So that the polyamide graft has a monoamine end group, it is sufficient to use a chain limiter of formula:

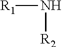

in which:
R₁ is hydrogen or a linear or branched alkyl group containing up to 20 carbon atoms; and
R₂ is a group having up to 20 carbon atoms that is a linear or branched alkyl or alkenyl group, a saturated or unsaturated cycloaliphatic radical, an aromatic radical or a combination of the preceding. The limiter may be, for example, laurylamine or oleylamine.

So that the polyamide graft has a carboxylic monoacid end group, it is sufficient to use a chain limiter of formula R′1-COOH, R′1-CO—O—CO—R′2 or a carboxylic diacid.

R′1 and R′2 are linear or branched alkyl groups containing up to 20 carbon atoms.

Advantageously, the polyamide graft has one end group having an amine functionality. The preferred monofunctional polymerization limiters are laurylamine and oleylamine.

Advantageously, the polyamide grafts have a molar mass between 1000 and 5000 g/mol and preferably between 2000 and 3000 g/mol.

The polycondensation defined above is carried out according to commonly known processes, for example at a temperature generally between 200° C. and 300° C., under vacuum or in an inert atmosphere, with stirring of the reaction mixture. The average chain length of the graft is determined by the initial molar ratio between the polycondensable monomer or the lactam and the monofunctional polymerization limiter. For the calculation of the average chain length, one chain limiter molecule is usually counted per one graft chain.

A person skilled in the art will only have to select the types and ratio of monomers and also choose the molar masses of the polyamide grafts in order to be able to easily obtain the desired values of the glass transition temperature, optionally of the melting temperature and also of the viscosity of the polyamide graft.

The condensation reaction of the polyamide graft on the polyolefin backbone containing the residue of (X) is carried out by reaction of one amine or acid function of the polyamide graft with the residue of (X).

Advantageously, monoamine polyamide grafts are used and amide or imide bonds are created by reacting the amine function with the function of the residue of (X).

This condensation is preferably carried out in the melt state. To manufacture the composition according to the invention, it is possible to use conventional kneading and/or extrusion techniques. The components of the composition are thus blended to form a compound which may optionally be granulated on exiting the die. Advantageously, coupling agents are added during the compounding.

To obtain a nanostructured composition, it is thus possible to blend the polyamide graft and the backbone in an extruder, at a temperature generally between 200° C. and 300° C. The average residence time of the molten material in the extruder may be between 5 seconds and 5 minutes, and preferably between 20 seconds and 1 minute. The efficiency of this condensation reaction is evaluated by selective extraction of free polyamide grafts, that is to say those that have not reacted to form the polyamide graft polymer.

The preparation of polyamide grafts having an amine end group and also their addition to a polyolefin backbone containing the residue of (X) is described in U.S. Pat. No. 3,976,720, U.S. Pat. No. 3,963,799, U.S. Pat. No. 5,342,886 and FR 2291225.

The polyamide graft polymer of the present invention advantageously has a nanostructured organization. To obtain this type of organization, use will preferably be made, for example, of grafts having a number-average molar mass Mₙ between 1000 and 5000 g/mol and more preferably between 2000 and 3000 g/mol.

### I.b.1. Characteristics Specific to the First Type of Molecule Forming the Core Layer of the Encapsulant According to the Invention:

In addition to the common characteristics, this first type of molecule envisaged for forming the core layer of the encapsulant is furthermore defined by the fact that the polyolefin backbone and the polyamide graft are chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone.

Moreover, the polyolefin backbone has a melting temperature of greater than or equal to 95° C.

The flow temperature of the polyamide graft polymer is defined as the highest temperature among the melting temperatures and the glass transition temperatures of the polyamide grafts and of the polyolefin backbone.

Use will also preferably be made of 15% to 30% by weight of polyamide grafts and a number of monomers (X) between 1.3 and 10.

### I.b.2. Characteristics Specific to the Second Type of Molecule Forming the Core Layer of the Encapsulant According to the Invention:

In this case use will be made of 15% to 50% by weight of polyamide grafts and a number of monomers (X) between 1.3 and 10.

For this second type of molecule forming the core layer of the encapsulant according to the invention, besides the common characteristics stated previously, the backbone and the grafts are chosen so that the flow temperature of the polyamide graft polymer is greater than 160° C., which enables a processing temperature that is particularly well suited to the current techniques for manufacturing solar panels.

### II. The Skin Layer of the Encapsulant

The composition of the skin layer is identical to that which is presented in I regarding the core layer, in point I.a) relating to the “common characteristics” for said core layer and in point I.b.1 relating to one of the embodiments of the core layer with, nevertheless, a significant difference in that, for the skin layer, the polyolefin backbone does not have a melting temperature or has a melting temperature below 95° C.

Crosslinking/Preparation of the Encapsulant and Production of an Encapsulant Film According to the Invention (Intended to be Incorporated into a Photovoltaic Module):

Regarding the encapsulant, although crosslinking is not obligatory, it is possible in order to further improve the thermomechanical properties of the encapsulant, in particular when the temperature becomes very high. It would not therefore be outside of the scope of the invention if crosslinking agents are added. As examples, mention may be made of isocyanates or organic peroxides. This crosslinking may also be carried out by known irradiation techniques. This crosslinking may be carried out by one of many methods known to a person skilled in the art, in particular by the use of thermally activated initiators, for example peroxides and azo compounds, photoinitiators such as benzophenone, by radiation techniques comprising light rays, UV rays, electron beams and X-rays, vinylsilane such as for example vinyltriethoxysilane or vinyltrimethoxysilane, and moisture crosslinking. The manual entitled “Handbook of Polymer Foams and Technology”, on pages 198 to 204, provides additional information to which a person skilled in the art may refer.

Regarding the aspects of the invention relating to the use of the thermoplastic composition in a photovoltaic module, a person skilled in the art may refer, for example, to the Handbook of Photovoltaic Science and Engineering, Wiley, 2003. Indeed, the composition of the invention may be used as an encapsulant or encapsulant-backsheet in a photovoltaic module, the structure of which is described in relation to the appended figures.

### Materials Used for Forming the Formulations Tested:

### Apolhya Solar® LC3UV:

The Apolhya Solar® family is a family of polymers sold by ARKEMA which combine the properties of polyamides with those of polyolefins owing to co-continuous morphologies being obtained on the nanometer scale. Apolhya Solar® LC3UV is one of the grades of the Apolhya Solar® family which is characterized by an MFI (Melt Flow Index) of 10 grams/10 minutes at 230° C. under 2.16 kg sold by the applicant. This product has an elastic modulus of 65 MPa at ambient temperature and the melting point of the polyolefin backbone is 85° C.

### Apolhya® LC4UV:

Apolhya Solar® LC4UV is one of the grades of the Apolhya Solar® family which is characterized by an MFI (Melt Flow Index) of 35 grams/10 minutes at 190° C. under 2.16 kg sold by the applicant. This product has an elastic modulus of 130 MPa at ambient temperature and the melting point of the polyolefin backbone is 105° C.

### Apolhya® LP91H3:

The Apolhya® family is a family of polymers sold by ARKEMA which combine the properties of polyamides with those of polyolefins owing to co-continuous morphologies being obtained on the nanometer scale. Within the context of the tests, Apolhya® LP91H3 is used here, which is one of the grades of the Apolhya® family suitable for use as a backsheet. This grade is characterized by an MFI (Melt Flow Index) of 3.0 grams/10 minutes at 230° C. under 2.16 kg (AE) and a melting point of 220° C.

### Obtaining the Films and Formulations Tested:

### Case of LC3UV/LC4UV/LC3UV Structures

Multilayer films were produced by calendering on an AMUT® brand extrusion line. This line is composed of two extruders:
Amut® (70 mm×33 D) equipped with a barrier screw;
Stork (40 mm×24 D) equipped with a degassing screw.

The line is also equipped with a fixed coextrusion block (fixed feedblock) with sets of cassettes in order to easily change structures, and a 650 mm coat hanger die. The main extruder is equipped with a filtration system. The coextrusion block allows the production of a film having three layers (layer 1/layer 2/layer 3) with a variable distribution of thicknesses (10%/80%/10%). As a nonlimiting example, it could be envisaged that the process parameters were set in the following way:
extrusion temp for layers 1 and 3: 150° C.;
extrusion temp for layer 2: 150° C.;
coextrusion box and die temp: 150° C.;
temp for rolls 1, 2 and 3=50, 50, 35;
line speed is 3 m/min (meters per minute);
die gap set at 800 microns;
total thickness: 400 microns (50/300/50).

A person skilled in the art will easily find in the literature an operating diagram for the line in order to illustrate the distribution of the layers and the tracking of the passage of the sheet over the rolls.

### Case of LC3UV/LP91H3/LC3UV Structures

Multilayer films were produced by cast-film extrusion on a Dr COLLIN brand extrusion line. This line is composed of three extruders equipped with a standard polyolefin screw profile, a variable coextrusion block (variable feedblock), and a 250 mm coat hanger die. The coextrusion block allows the production of a film having three layers (layer 1/layer 2/layer 3) with a variable distribution of thicknesses (e.g.: 50/300/50 microns). In the particular and nonlimiting case of the examples presented in the patents, the process parameters were set:
extrusion temp for layers 1 and 3: 180° C.;
extrusion temp for layer 2: 240° C. depending on the polymers to be extruded;
coextrusion box and die temp: 220° C.;
line speed is 2.6 m/min.

The final film is cut in order to obtain a useful width of 100 cm in order to take account of the significant encapsulation phenomenon.

### Tests Carried Out on the Test Specimens:

### Test of Adhesion to a Layer of Glass:

The adhesion to glass was evaluated according to the following protocol. A glass/encapsulant film/backsheet structure is laminated for 15 minutes at 150° C. using the laminator from Penergy®. The thickness of the encapsulant film is 400 μm. The backsheet is made of KPE (Kynar/PET/EVA). The adhesion at the glass/encapsulant interface is evaluated using a 90° peel test carried out at 100 mm/min on a Zwick 1445 tensile testing machine. The width of the peel arm is 15 mm (millimeters). The peel strength is expressed in N/15 mm (newtons per 15 minutes).

Tests were also carried out on the encapsulant in order to verify that this novel structure retains excellent properties, that is to say identical properties, relative to the properties of an encapsulant in accordance with that described in document WO 09/138,679, namely in particular regarding its transparency, its mechanical, thermomechanical and flame retardant properties and its electrical insulation properties. These tests proved to be positive.

The compositions according to the invention therefore fulfill the criteria for being able to be very advantageously used as a binder or encapsulant in solar modules.

The composition examples according to the invention all have the same thicknesses regarding the skin layer and core layer but it is clearly understood that a person skilled in the art could vary them as a function of the application of the photovoltaic module and of the performances of the latter with regard to the intrinsic properties of the skin layer and of the core layer, notwithstanding the synergy produced between these two layers that form the encapsulant.

The present invention is illustrated in greater detail by the following nonlimiting examples.

### Example 1

The film is a 400 μm three-layer film consisting of two outer layers of Apolhya Solar® LC3-UV of 50 μm (micrometers) each and of a 300 μm central layer of Apolhya Solar® LC4-UV.

### Example 2

The film is a 400 μm three-layer film consisting of two outer layers of Apolhya Solar® LC3-UV of 50 μm each and of a 300 μm core layer of Apolhya® LP91H3.

### Comparative Example 1

The film is a 400 μm single-layer film consisting of Apolhya Solar® LC4-UV.

### Comparative Example 2

The film is a 400 μm single-layer film consisting of Apolhya® LP91H3.

### Results of the Tests Carried Out on the Test Specimens of Various Formulations:

| | Outer layer | Inner layer | Outer layer | Adhesion |
|---|---|---|---|---|
| | (50 μm) | (300 μm) | (50 μm) | N/15 mm |
| Example 1 | LC3-UV | LC4-UV | LC3-UV | >15 |

| | | |
|---|---|---|
| Comparative | LC4-UV | 0 |
| example 1 | | |

| | Outer layer | Inner layer | Outer layer | Adhesion |
|---|---|---|---|---|
| | (50 μm) | (300 μm) | (50 μm) | N/15 mm |
| Example 2 | LC3-UV | LP91H3 | LC3-UV | >15 |

| | | |
|---|---|---|
| Comparative | LP91H3 | 0 |
| example 2 | | |

1. A photovoltaic module encapsulant, adapted to encase a photovoltaic cell, the encapsulant comprising two adjacent thermoplastic layers, a core layer and a skin layer, forming a core-skin assembly, wherein:
the core layer consists of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
the polyamide graft is attached to the polyolefin backbone by the residue of the unsaturated monomer (X) comprising a function capable of reacting via a condensation reaction with a polyamide having at least one amine end group and/or at least one carboxylic acid end group,
the residue of the unsaturated monomer (X) is attached to the backbone by grafting or copolymerization,
the skin layer consists of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
the polyamide graft is attached to the polyolefin backbone by the residue of the unsaturated monomer (X) comprising a function capable of reacting via a condensation reaction with a polyamide having at least one amine end group and/or at least one carboxylic acid end group,
the residue of the unsaturated monomer (X) is attached to the backbone by grafting or copolymerization,
the polyolefin backbone and the polyamide graft being chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone.

2. The encapsulant as claimed in claim 1, wherein the skin layer and the core layer are nanostructured.

3. The encapsulant as claimed in claim 1, wherein, for the core layer as for the skin layer, the number-average molar mass of polyamide graft is within the range extending from 1000 to 5000 g/mol.

4. The encapsulant as claimed in claim 1, wherein, for the core layer as for the skin layer, the number of monomers (X) attached to the polyolefin backbone is greater than or equal to 1.3 and/or less than or equal to 10.

5. The encapsulant as claimed in claim 1, wherein the polyolefin backbone and the polyamide graft of the core layer are chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone.

6. The encapsulant as claimed in claim 1, wherein, for the core layer as for the skin layer, the at least one polyamide graft comprises at least one copolyamide.

7. The encapsulant as claimed in claim 1, wherein, for the core layer, the polyolefin backbone has a melting temperature of greater than or equal to 95° C.

8. The encapsulant as claimed in claim 1, wherein, for the skin layer, the polyolefin backbone does not have a melting temperature or has a melting temperature below 95° C.

9. The encapsulant as claimed in claim 1, wherein the polyolefin backbone and the polyamide graft of the core layer are chosen so that said polyamide graft polymer has a flow temperature of greater than 160° C., this flow temperature being defined as the highest temperature among the melting temperatures and glass transition temperatures of the polyamide graft and of the polyolefin backbone.

10. The encapsulant as claimed in claim 1, wherein the encapsulant consists of two adjacent layers that form a core-skin assembly or of three adjacent layers that form a skin-core-skin assembly where the two skin layers surround the core layer and are optionally identical.

11. A photovoltaic module comprising the encapsulant as claimed in claim 1.

12. A photovoltaic module comprising a structure consisting of a combination of at least one encapsulant and a frontsheet or a backsheet, wherein the encapsulant is as claimed in claim 1.

13. The encapsulant as claimed in claim 1, wherein, for the core layer as for the skin layer, the number-average molar mass of polyamide graft is within the range extending from 2000 to 3000 g/mol.

14. The encapsulant as claimed in claim 7, wherein, for the skin layer, the polyolefin backbone does not have a melting temperature or has a melting temperature below 95° C.

15. The encapsulant as claimed in claim 10, wherein the encapsulant consists of three adjacent layers that form a skin-core-skin assembly, where the two skin layers surround the core layer and are identical.
